(19) United States
(12) Patent Application Publication
(10) Pub. No.: US 2009/0053020 A1
(43) Pub. Date: Feb. 26, 2009

(54) SUBSTRATE PROCESSING APPARATUS

(76) Inventor: Eiji Okuno, Kyoto-shi (JP)

Correspondence Address: OSTROLENK FABER GERB & SOFFEN, 1180 AVENUE OF THE AMERICAS, NEW YORK, NY, 100368403, US

(21) Appl. No.: 12/194,880

(22) Filed: Aug. 20, 2008

(30) Foreign Application Priority Data
Aug. 21, 2007 (JP) 2007-214648

(51) Int. Cl. H01L 21/68

(52) U.S. Cl. 414/222.01

(57) ABSTRACT

An indexer robot includes first and second substrate holding mechanisms, first and second lifting/lowering mechanisms, a rotation mechanism and a moving mechanism. The first and second substrate holding mechanisms have arms and hands and provided on the first and second lifting/lowering mechanisms, respectively. The first and second lifting/lowering mechanisms can lift the first and second substrate holding mechanisms independently from each other. The first and second lifting/lowering mechanisms are provided on the rotation mechanism. The rotation mechanism is provided on the moving mechanism.

### BACKGROUND OF THE INVENTION

1. Field of the Invention

The present invention relates to a substrate processing apparatus that processes substrates.

2. Description of the Background Art

Substrate processing apparatuses have been used to carry out various kinds of processing to substrates such as a semiconductor wafer, a glass substrate for a photomask, a glass substrate for a liquid crystal display, and a glass substrate for an optical disk.

For example, JP 2005-85882 A discloses a substrate processing apparatus including a substrate transport robot that transports a substrate in an approximate center of a rectangular processing region. A plurality of (four for example) substrate chemical treatment units are provided to surround the substrate transfer robot.

An indexer unit including an indexer robot is provided on one end side of the processing region. A plurality of cassettes used to store substrates are placed at the indexer unit. The indexer robot takes out an unprocessed substrate from any one of the cassettes, and transfers the substrate to the substrate transport robot while receiving a processed substrate from the substrate transport robot and stores the substrate to the cassette.

The indexer robot is provided with hands used to hold a substrate. For example, an indexer robot has two hands provided one above the other in the vertical direction at a predetermined distance therebetween. The indexer robot takes out a substrate from a cassette and stores a substrate to the cassette as follows.

The indexer robot moves to a position at the front of a cassette as it holds a processed substrate received from the substrate transport robot at its lower hand. There are a plurality of shelves in the cassette. Then, the height of the upper hand is adjusted to the height of a shelf in the cassette that stores a substrate. The upper hand is advanced into the cassette while it is slightly lifted to hold the substrate in the cassette and withdrawn. In this way, the unprocessed substrate can be taken out from the cassette.

Then, the lower hand that holds the substrate is adjusted to the height of a shelf in the cassette to which the substrate should be stored. The lower hand is then advanced into the cassette while it is slightly lowered to place the substrate on the shelf in the cassette and then withdrawn. In this way, the processed substrate can be stored in the cassette.

In the indexer robot as described above, the time for adjusting the height of the upper hand and the time for adjusting the height of the lower hand are separately required. Furthermore, the time for the upper hand to store a substrate and the time for the lower hand to take out a substrate are separately required. This makes it difficult to reduce the operation time of the indexer robot during taking out and storing substrates from and to the cassettes. This prevents the throughput from being improved in the substrate processing apparatus.

### SUMMARY OF THE INVENTION

It is an object of the invention to provide a substrate processing apparatus having improved throughput.

(1) A substrate processing apparatus according to the present invention includes a processing section used to carry out processing to a substrate, and an indexer used to carry in/out a substrate to/from the processing section, the indexer includes a container platform where a storing container that stores a plurality of substrates in a plurality of stages is placed, and a first substrate transport device that transports a substrate between the storing container placed at the container platform and the processing section, and the first substrate transport device includes first and second substrate holders provided one above the other in the vertical direction to hold a substrate, a moving mechanism provided movably in an approximately horizontal direction and rotatably around an approximately vertical axis, first advancing/withdrawing mechanism that advances/withdraws the first substrate holder in an approximately horizontal direction, second advancing/withdrawing mechanism that advances/withdraws the second substrate holder in an approximately horizontal direction, first lifting/lowering mechanism that lifts/lowers the first advancing/withdrawing mechanism with respect to the moving mechanism in an approximately vertical direction, and second lifting/lowering mechanism that lifts/lowers the second advancing/withdrawing mechanism with respect to the moving mechanism in an approximately vertical direction.

In the substrate processing apparatus, a storing container having a plurality of unprocessed substrates stored in a plurality of stages are placed on a container platform for the indexer. An unprocessed substrate is taken out from the storing container by the first substrate transport device and transported to the processing section. In the processing section, the substrate is processed. The processed substrate is again stored by the storing container by the first substrate transport device.

When an unprocessed substrate is taken out from the storing container and a processed substrate is stored in the storing container, the first substrate transport device moves to a position opposed to the storing container by the moving mechanism while one of the first and second substrate holders holds the processed substrate. The first and second substrate holders are adjusted to prescribed heights by the first and second lifting/lowering mechanisms, respectively.

Then, the first substrate transport device simultaneously advances the first and second substrate holders and allows them to enter the storing container. Then, the first substrate transport device lowers one of the first and second substrate holders and lifts the other by the first and second lifting/lowering mechanisms. In this way, the processed substrate held by one of the first and second substrate holders can be stored in the storing container and the unprocessed substrate stored in the storing container is held by the other of the first and second substrate holders. Then, the first substrate transport device simultaneously withdraws the first and second substrate holders by the first and second advancing/withdrawing mechanisms.

In this way, the first substrate transport device can take out an unprocessed substrate from the storing container and store a processed substrate to the storing container at the same time. Therefore, the time required for the operation of the first substrate transport device can be reduced. Consequently, the throughput in the substrate processing apparatus can be improved.

The distance between the first and second substrate holders can arbitrarily be adjusted by the first and second lifting/lowering mechanisms, and therefore, substrates can surely be taken out and stored at the same time if the position from which an unprocessed substrate in the storing container should be taken out and a position to which a processed substrate should be stored are not constant. Therefore, the time required for the operation of the first substrate transport device can surely be reduced.

(2) The storing container may have a plurality of shelves each used to store a substrate, the first substrate transport device may be opposed to the storing container by the moving mechanism while holding a substrate by the first substrate holder and holding no substrate by the second substrate holder, the first substrate holder may be adjusted to the height of a shelf in the storing container on which no substrate is stored by the first lifting/lowering mechanism, the second substrate holder may be adjusted to the height of a shelf in the storing container on which a substrate is stored by the second lifting/lowering mechanism, the first and second substrate holders may simultaneously be advanced into the storing container by the first and second advancing/withdrawing mechanisms, the first substrate holder may be lowered by the first lifting/lowering mechanism while the second substrate holder is lifted by the second lifting/lowering mechanism, and the first and second substrate holders may simultaneously be withdrawn from the storing container by the first and second advancing/withdrawing mechanisms.

In this case, the first substrate transport device can store a processed substrate held by the first substrate holder on a shelf in the storing container with no substrate stored thereon while taking out an unprocessed substrate from a shelf in the storing container by the second substrate holder. Therefore, the time required for the operation of the first substrate transport device can be reduced. Consequently, the throughput in the substrate processing apparatus can be improved.

(3) The storing container may have a plurality of shelves each used to store a substrate, the first substrate transport device may be opposed to the storing container by the moving mechanism while holding no substrate by the first substrate holder and holding a substrate by the second substrate holder, the first substrate holder may be adjusted to the height of a shelf in the storing container on which a substrate is stored by the first lifting/lowering mechanism while the second holder may be adjusted to the height of a shelf in the storing container on which no substrate is stored by the second lifting/lowering mechanism, the first and second substrate holders may simultaneously be advanced into the storing container by the first and second advancing/withdrawing mechanisms, the first substrate holder may be lifted by the first lifting/lowering mechanism while the second substrate holder is lowered by the second lifting/lowering mechanism, and the first and second substrate holders may simultaneously be withdrawn from the storing container by the first and second advancing/withdrawing mechanisms.

In this way, the first substrate transport device takes out an unprocessed substrate from a shelf in the storing container by the first substrate holder while storing a processed substrate held by the second substrate holder to a shelf in the storing container with no substrate stored thereon. Therefore, the time required for the operation of the first substrate transport device can be reduced. Consequently, the throughput in the substrate processing apparatus can be improved.

(4) The substrate processing apparatus may further include an interface device that receives and transfers substrates between the processing section and the indexer, the interface device may include third and fourth substrate holders provided one above the other in the vertical direction to hold a substrate, and a first opening/closing driving mechanism that drives the third and fourth substrate holders in a direction in which the third and fourth substrate holders become apart from each other and in a direction in which the third and fourth substrate holders come closer to each other, the processing section may include a processing unit that processes a substrate and a second substrate transport device that transports a substrate between the interface device and the processing unit, and the second substrate transport device may include fifth and sixth substrate holders provided one above the other in the vertical direction to hold a substrate.

In this case, the first substrate transport device transfers an unprocessed substrate to the interface device and receives a processed substrate from the interface device. The interface device transfers an unprocessed substrate to the second substrate transport device and receives a processed substrate from the second substrate transport device. The second substrate transport device carries in the unprocessed substrate and carries out the processed substrate to/from the processing unit.

When substrates are received and transferred between the first substrate transport device and the interface device, the first substrate transport device and the interface device are opposed to each other while the first substrate transport device holds an unprocessed substrate by one of the first and second substrate holders and the interface device holds a processed substrate by one of the third and fourth substrate holders. Then, the first substrate transport device advances the first and second substrate holders to a position where the first and second substrate holders are placed above the third and fourth substrate holders of the interface device in the vertical direction in an overlapped manner.

In the state, the interface device changes the distance between the third and fourth substrate holders by the first opening/closing driving mechanism. In this way, the unprocessed substrate held by one of the first and second substrate holders of the first substrate transport device is transferred to the other of the third and fourth substrate holders of the interface device. At the same time, the processed substrate held by one of the third and fourth substrate holders of the interface device is transferred to the other of the first and second substrate holders of the first substrate transport device.

In this way, an unprocessed substrate can be received and transferred from the first substrate transport device to the interface device and a processed substrate can be received and transferred from the interface device to the first substrate transport device at the same time.

When substrates are received and transferred between the interface device and the second substrate transport device, the interface device and the second substrate transport device are opposed to each other while the interface device holds the unprocessed substrate by the other of the third and fourth substrate holders and the second substrate transport device holds the processed substrate by one of the fifth and sixth substrate holders. The second substrate transport device advances the fifth and sixth substrate holders to a position where the fifth and sixth substrate holders are placed above the third and fourth substrate holders in an overlapped manner in the vertical direction.

In the state, the interface device changes the distance between the third and fourth substrate holders by the first opening/closing mechanism. In this way, the unprocessed substrate held by the other of the third and fourth substrate holders of the interface device is transferred to the other of the fifth and sixth substrate holders of the second substrate transport device. At the same time, the processed substrate held by one of the fifth and sixth substrate holders of the second substrate transport device is transferred to one of the third and fourth substrate holders of the interface device.

In this way, the unprocessed substrate can be received and transferred from the interface device to the substrate transport device and the processed substrate can be received and transferred from the second substrate transport device to the interface device at the same time.

Therefore, substrates are received and transferred between the first substrate transport device and the interface device and between the interface device and the second substrate transport device in a short period of time. Consequently, the throughput in the substrate processing apparatus can further be improved.

(5) The substrate processing apparatus may further include an interface device that receives and transfers substrates between the processing section and the indexer, the interface device may include third and fourth substrate holders provided one above the other in the vertical direction to hold a substrate, the processing section may include a processing unit that processes a substrate and a second substrate transport device that transports a substrate between the interface device and the processing unit, the second substrate transport device may include fifth and sixth substrate holders provided one above the other in the vertical direction to hold a substrate, and a second opening/closing driving mechanism that drives the fifth and sixth substrate holders in a direction in which the fifth and sixth substrate holders become apart from each other and in a direction in which the fifth and sixth substrate holders come closer to each other.

In this way, when substrates are received and transferred between the first substrate transport device and the interface device, the first substrate transport device and the interface device are opposed to each other while the first substrate transport device holds an unprocessed substrate by one of the first and second substrate holders and the interface holds a processed substrate by one of the third and fourth substrate holders. The first substrate transport device then advances the first and second substrate holders to a position where the first and second substrate holders are placed above the third and fourth substrate holders of the interface device in an overlapped manner in the vertical direction.

In the state, the first substrate transport device changes the distance between the first and second substrate holders by the first and second lifting/lowering mechanism. In this way, the unprocessed substrate held by one of the first and second substrate holders of the first substrate transport device is transferred to the other of the third and fourth substrate holders of the interface device. At the same time, the processed substrate held by one of the third and fourth substrate holders of the interface device is transferred to the other of the first and second substrate holders of the first substrate transport device.

In this way, the unprocessed substrate can be received and transferred from the first substrate transport device to the interface device and the processed substrate can be received and transferred from the interface device to the first substrate transport device at the same time.

When substrates are received and transferred between the interface device and the second substrate transport device, the interface device and the second substrate transport device are opposed to each other while the interface device holds an unprocessed substrate by the other of the third and fourth substrate holders and the second substrate transport device holds a processed substrate by one of the fifth and sixth substrate holders. The second substrate transport device advances the fifth and sixth substrate holders to a position where the fifth and sixth substrate holders are placed above the third and fourth substrate holders of the interface device in an overlapped manner in the vertical position.

In the state, the second substrate transport device changes the distance between the fifth and sixth substrate holders by the second opening/closing driving mechanism. In this way, the unprocessed substrate held by the other of the third and fourth substrate holders of the interface is transferred to the other of the fifth and sixth substrate holders of the second substrate transport device. At the same time, the processed substrate held by one of the fifth and sixth substrate holders of the second substrate transport device is transferred to one of the third and fourth substrate holders of the interface device.

In this way, the unprocessed substrate can be received and transferred from the interface device to the second substrate transport device and the processed substrate can be received and transferred from the second substrate transport device to the interface device at the same time.

Therefore, substrates are received and transferred between the first substrate transport device and the interface device and between the interface and the second substrate transport device in a short period of time. Consequently, the throughput in the substrate processing apparatus can further be improved.

(6) The processing section may include a processing unit that processes a substrate and a second substrate transport device that transports a substrate between the first substrate transport device and the processing unit, and the second substrate transport device may have fifth and sixth substrate holders provided one above the other in the vertical direction to hold a substrate.

In this case, the first substrate transport device transfers an unprocessed substrate to the second substrate transport device and receives a processed substrate from the second substrate transport device. The second transport device carries in the unprocessed substrate to the processing unit and carries the processed substrate out from the processing unit.

When substrates are received and transferred between the first and second substrate transport devices, the first and second substrate transport devices are opposed to each other while one of the first and second substrate holders of the first substrate transport device holds an unprocessed substrate and the second substrate transport device holds a processed substrate by one of the fifth and sixth substrate holders. The first substrate transport device advances the first and second substrate holders and the second substrate transport device advances the fifth and sixth substrate holders so that the first and second substrate transport devices are placed above the fifth and sixth substrate holders in an overlapped manner in the vertical direction.

In this state, the first substrate transport device changes the distance between the first and second substrate holders by the first and second lifting/lowering mechanisms. In this way, the unprocessed substrate held by one of the first and second substrate holders of the first substrate transport device is transferred to the other of the fifth and sixth substrate holders of the second substrate transport device. At the same time, the processed substrate held by one of the fifth and sixth substrate holders of the second substrate transport device is transferred to the other of the first and second substrate holders of the first substrate transport device.

In this way, an unprocessed substrate can be received and transferred between the first substrate transport device and the second substrate transport device and a processed substrate can be received and transferred between the second substrate transport device and the first substrate transport device at the same time. Therefore, substrates are received and transferred between the first and second substrate transport devices in a short period of time. Consequently, the throughput in the substrate processing apparatus can further be improved.

Other features, elements, characteristics, and advantages of the present invention will become more apparent from the following description of preferred embodiments of the present invention with reference to the attached drawings.

### BRIEF DESCRIPTION OF THE DRAWINGS

FIG. 1 is a plan view of the structure of a substrate processing apparatus according to a first embodiment.

FIG. 2 is a sectional view taken along line K1-K1 in FIG. 1.

FIG. 3 is a sectional view taken along line K2-K2 in FIG. 1.

FIG. 4 shows a carrier in detail.

FIGS. 5 and 6 are schematic side views for use in illustrating the operation of taking out and storing substrates from and to the carrier by the indexer robot.

FIG. 7 is a schematic side view for use in illustrating the operation of receiving and transferring substrates between the indexer robot and a shuttle transport mechanism.

FIG. 8 is a schematic side view for use in illustrating the operation of receiving and transferring substrates between the shuttle transport mechanism and a substrate transport robot.

FIGS. 9 and 10 are schematic side views for use in illustrating other examples of the operation of taking out and storing substrates by the indexer robot.

FIG. 11 is a sectional view of a substrate processing apparatus according to a second embodiment.

FIG. 12 is a schematic side view for use in illustrating the operation of receiving and transferring substrates between an indexer robot and a shuttle transport mechanism according to the second embodiment.

FIG. 13 is a view for use in illustrating the operation of receiving and transferring substrates between the shuttle transport mechanism and a substrate transport robot according to the second embodiment.

FIG. 14 is a plan view of a substrate processing apparatus according to a third embodiment.

FIG. 15 is a view for use in illustrating the operation of receiving and transferring substrates between an indexer robot and a substrate transport robot according to the third embodiment.

### DESCRIPTION OF THE PREFERRED EMBODIMENTS

Now, substrate processing apparatuses according to embodiments of the invention will be described in conjunction with the accompanying drawings.

In the following description, the term “substrate” refers to a semiconductor wafer, a glass substrate for a liquid crystal display, a glass substrate for a PDP (plasma display panel), a glass substrate for a photomask, a substrate for an optical disk or the like.

### (1) First Embodiment

### (1-1) Structure of Substrate Processing Apparatus

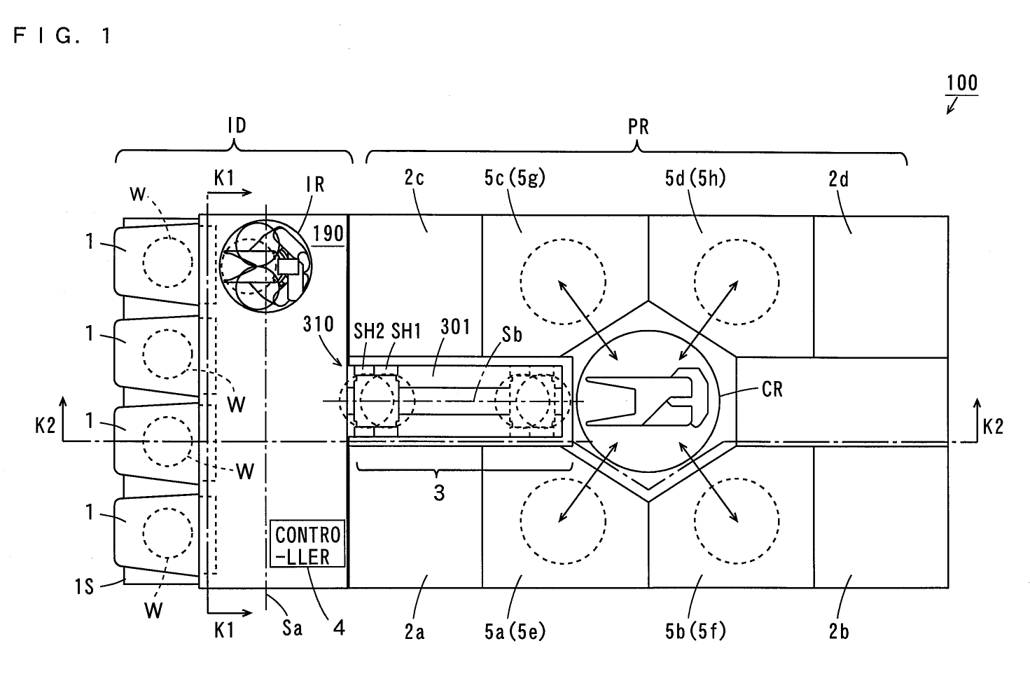

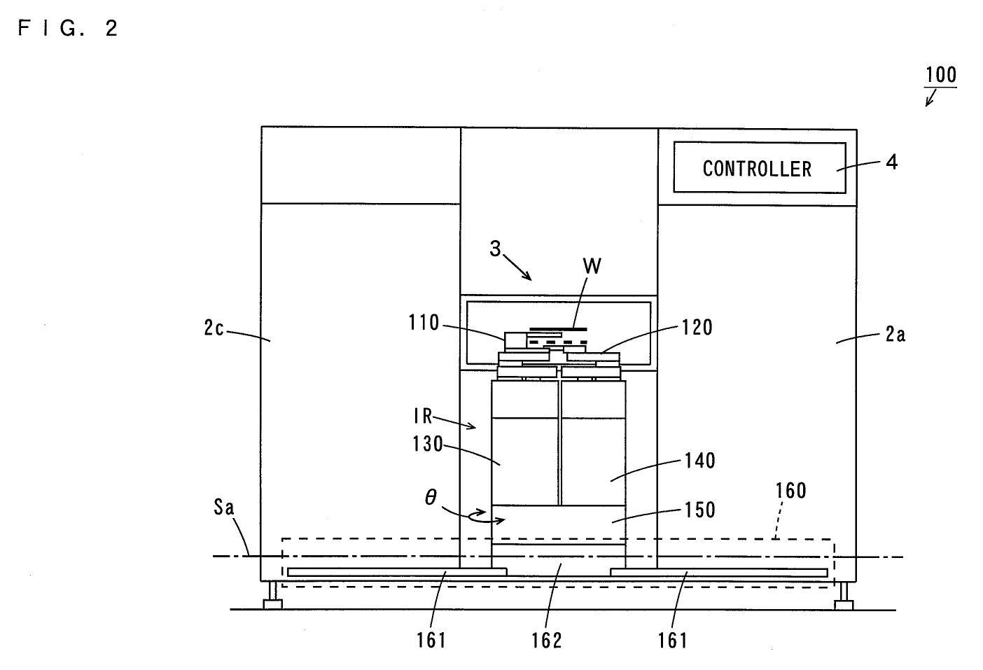

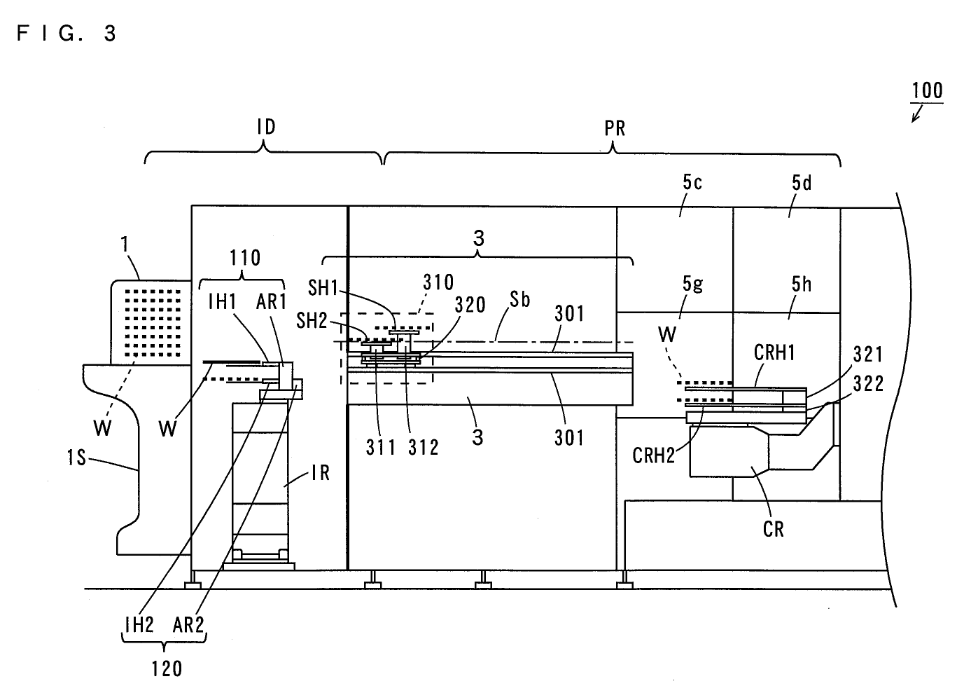

FIG. 1 is a plane view of the structure of a substrate processing apparatus according to a first embodiment of the invention. FIG. 2 is a sectional view taken along line K1-K1 in FIG. 1, and FIG. 3 is a sectional view taken along line K2-K2 in FIG. 1.

As shown in FIG. 1, the substrate processing apparatus 100 has an indexer ID and a processing section PR adjacent to each other. In the indexer ID, a substrate transport path 190 that extends along a first axis Sa in the horizontal direction is formed adjacent to one end of the processing section PR. A carrier platform 1S is provided along a side of the substrate transport path 190. Four carriers 1 each storing a plurality of substrates W are placed at carrier platform 1S.

An indexer robot IR is provided in the substrate transport path 190 and transports substrates W between the four carriers 1 and the processing section PR. The indexer robot IR is provided movably along the first axis Sa in the substrate transport path 190.

A controller 4 is provided in a part of the indexer ID. The controller 4 includes a computer or the like including a CPU (central processing unit) and controls various elements in the substrate processing apparatus 100.

A substrate transport robot CR is provided in the center of the processing section PR. Cleaning processing units 5a to 5h and an interface 3 are provided to surround the substrate transport robot CR.

The cleaning processing units 5a to 5d are placed on cleaning processing units 5e to 5h and the cleaning processing units 5a, 5b, 5e, and 5f are opposite to the cleaning processing units 5d, 5c, 5h, and 5g respectively with the substrate transport robot CR therebetween. The cleaning processing units 5a to 5h carry out cleaning processing to a substrate W with a processing liquid such as BHF (buffered hydrofluoric acid), DHF (diluted hydrofluoric acid) and hydrofluoric acid.

Fluid boxes 2a to 2d are provided at the four corner of the processing section PR. The fluid boxes 2a to 2d each store fluid related elements such as a pipe, a joint, a valve, a flowmeter, a regulator, a pump, a temperature adjuster, and a processing liquid storage tank used to supply the processing liquid to the cleaning processing units 5a to 5h and discharge the processing liquid out from the cleaning processing units 5a to 5h.

The interface 3 is provided to extend along a second axis Sb in the horizontal direction orthogonal to the first axis Sb. The interface 3 includes a transport rail 301 and a shuttle transport mechanism 310.

The transport rail 301 extends along the second axis Sb. The shuttle transport mechanism 310 reciprocates on the transport rail 301 as it holds a substrate W. In this way, the shuttle transport mechanism 310 transports the substrate W between one end of the interface 3 on the side of the indexer ID (hereinafter referred to as “first interface position”) and the other end on the side of the processing section PR (hereinafter referred to as “second interface position”).

As shown in FIG. 2, the indexer robot IR in FIG. 1 includes first and second substrate holding mechanisms 110 and 120, first and second lifting/lowering mechanisms 130 and 140, a rotation mechanism 150, and a moving mechanism 160.

The first and second substrate holding mechanisms 110 and 120 are provided on the first and second lifting/lowering mechanisms 130 and 140, respectively. The first and second lifting/lowering mechanisms 130 and 140 are provided on the rotation mechanism 150. The rotation mechanism 150 is provided on the moving mechanism 160.

As shown in FIG. 3, the first substrate holding mechanism 110 has an arm AR1 and a hand IH1, and the second substrate holding mechanism 120 has an arm AR2 and a hand IH2. The hands IH1 and IH2 are extended horizontally and supported by the arms AR1 and AR2, respectively. The hand IH1 is provided above the hand IH2 in an overlapped manner. As the arms AR1 and AR2 fold/stretch, the hands IH1 and IH2 are advanced/withdrawn in the horizontal direction. During the transport of a substrate W, the substrate W is each held on the upper surface side of the hands IH1 and IH2.

Referring back to FIG. 2, the first and second lifting/lowering mechanisms 130 and 140 independently lift/lower the first and second substrate holding mechanisms 110 and 120, respectively. The rotation mechanism 150 rotates the first and second lifting/lowering mechanisms 130 and 140 as denoted by the arrow θ around an axis in the vertical direction. The moving mechanism 160 has an indexer rail 161 and a moving platform 162. The indexer rail 161 is attached to the bottom of the substrate processing apparatus 100 along the first axis Sa. The moving platform 162 moves along the first axis Sa on the indexer rail 161.

In the above-described arrangement, the indexer robot IR carries out reciprocating operation in the horizontal direction along the first axis Sa, the operation of rotating the first and second substrate holding mechanisms 110 and 120 around an axis in the vertical direction, the operation of lifting/lowering the first and second substrate holding mechanisms 110 and 120 in the vertical direction, and the operation of advancing/withdrawing the hands IH1 and IH2.

As shown in FIG. 3, the shuttle transport mechanism 310 of the interface 3 has a shuttle moving device 320, hands SH1 and SH2 and lifting cylinders 311 and 312. The lifting cylinders 311 and 312 are fixed to the shuttle moving device 320. The hand SH1 is fixed to the upper end of the lifting cylinder 311 and the hand SH2 is fixed to the upper end of the lifting cylinder 312. During the transport of a substrate W, the substrate W is each held on the upper surface side of the hands SH1 and SH2.

The hands SH1 and SH2 are provided one above the other in the vertical direction. The hands SH1 and SH2 are switched between the open state in which they are apart from each other and the closed state in which they are close to each other by the lifting cylinders 311 and 312. Note that instead of the cylinders 311 and 312 that independently drive the hands SH1 and SH2, respectively, a switching mechanism that drives the hands SH1 and SH2 together and switch them between the open state and the closed state may be employed.

In the interface 3, the presence/absence of a substrate W on the hands SH1 and SH2 is detected by a sensor that is not shown. The hands SH1 and SH2 are arranged shifted from one another in the horizontal direction in order to alleviate the detection. Note that if the presence/absence of a substrate W on the hands SH1 and SH2 can be detected, the hand SH1 may be arranged immediately above the hand SH2.

The substrate transport robot CR has hands CRH1 and CRH2 and transport arms 321 and 322. The hands CRH1 and CRH2 are extended horizontally and supported by the transport arms 321 and 322 so that they overlap each other at a prescribed distance between them in the vertical direction. The distance between the hands CRH1 and CRH2 is smaller than the distance between the hands SH1 and SH2 of the shuttle transport mechanism 310 in the open state and larger than the distance in the closed state.

The transport arms 321 and 322 are lifted/lowered together by a lifting/lowering mechanism that is not shown and rotated together around an axis in the vertical direction by a rotation mechanism that is not shown.

### (1-2) Operation

Now, with reference to FIGS. 1 to 3, the operation of the indexer robot IR, the shuttle transport mechanism 310 and the substrate transport robot CR will sequentially be described. The operation of each element in the following paragraphs is controlled by the controller 4.

The indexer robot IR takes out an unprocessed substrate W from a carrier 1 by the hand IH2. Then, the indexer robot IR moves to a position opposed to the shuttle transport mechanism 310, receives a processed substrate W by the hand IH1 from the hand SH1 of the shuttle transport mechanism 310 and transfers the unprocessed substrate W held by the hand IH2 to the hand SH2 of the shuttle transport mechanism 310.

Then, the indexer robot IR moves to a position opposed to one of the carriers 1 and takes out an unprocessed substrate W from the carrier 1 by the hand IH2 and stores the processed substrate W held by the hand IH1 in the carrier 1. The indexer robot IR continuously carries out the operation.

The shuttle transport mechanism 310 receives the unprocessed substrate W by the hand SH2 from the hand IH2 of the indexer robot IR in the first interface position and then moves to the second interface position. The mechanism 310 receives a processed substrate W by the hand SH1 from the hand CRH1 of the substrate transport robot CR and transfers the unprocessed substrate W held by the hand SH2 to the hand CRH2 of the substrate transport robot CR.

Then, the shuttle transport mechanism 310 moves to the first interface position, receives an unprocessed substrate W by the hand SH2 from the hand IH2 of the indexer robot IR and transfers the processed substrate W held by the hand SH1 to the hand IH1 of the indexer robot IR. The shuttle transport mechanism 310 continuously carries out the operation.

The substrate transport robot CR receives the unprocessed substrate W by the hand CRH2 from the hand SH2 of the shuttle transport mechanism 310 and then rotates to oppose one of the cleaning processing units 5a to 5h. Then, a processed substrate W is taken out from one of the cleaning processing units 5a to 5h by the hand CRH1 and transfers the unprocessed substrate W held by the hand CRH2 to the same unit among the cleaning processing units 5a to 5h.

Then, the substrate transport robot CR rotates to oppose the shuttle transport mechanism 310, receives an unprocessed substrate W by the hand CRH2 from the hand SH2 of the shuttle transport mechanism 310 and transfers the processed substrate W held by the hand CRH1 to the hand SH1 of the shuttle transport mechanism 310. The substrate transport robot CR continuously carries out the operation.

By these kinds of operation by the indexer robot IR, the shuttle transport mechanism 310, and the substrate transport robot CR, unprocessed substrates W are sequentially transported from the carriers 1 to the cleaning processing units 5a to 5h and processed substrates W are sequentially transported from the cleaning processing units 5a to 5h to the carriers 1.

### (1-3) Details of Carriers

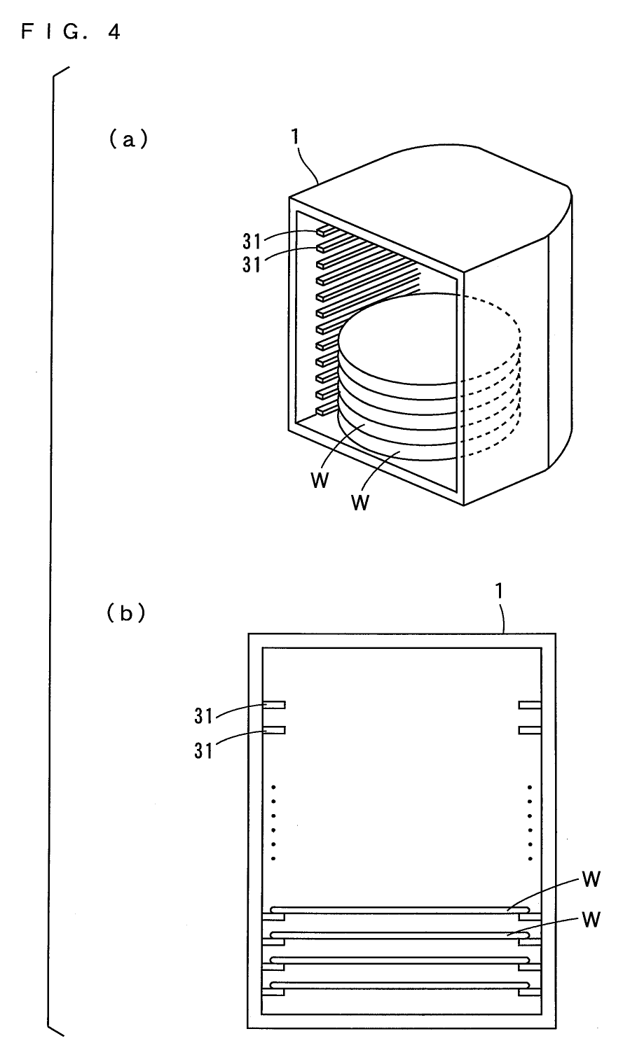

Now, details of the carriers 1 will be described. FIG. 4(a) is a perspective view of a carrier 1 and FIG. 4(b) is a front view of the carrier 1.

As shown in FIGS. 4(a) and 4(b), the carrier 1 has a box shape open at the front and a plurality of shelves 31 are provided to protrude from the side surfaces to the inner side. The plurality of shelves 31 are provided at prescribed intervals in the vertical direction and a substrate W is placed on each of the shelves 31.

According to the embodiment, the carrier 1 is capable of storing 25 substrates W. In the following description, the shelves will be referred to as the first, second, third, . . . , and the twenty-fifth shelves 31 sequentially from the uppermost shelf 31 to the lowermost shelf 31. According to the embodiment, unprocessed substrates W are taken out sequentially from the first to twenty-fifth shelves 31 in the carrier 1 and processed substrates W are sequentially stored in the shelves 31 in the carrier 1 in which they were stored before the processing.

Herein, during the operation of the substrate processing apparatus 100, substrates W are processed in parallel among the cleaning processing units 5a and 5h, while one substrate W is held by each of the indexer robot IR, the shuttle transport mechanism 310 and the substrate transport robot CR. More specifically, eleven substrates W in total are present outside the carrier 1. In this way, there are eleven shelves 31 with no substrate W thereon in the carrier 1.

For example, when an unprocessed substrate W is taken out from the twelfth shelf 31, no substrate W is stored on the first to eleventh shelves 31. In this case, a processed substrate W is stored on the first shelf 31. When an unprocessed substrate W is taken out from the sixteenth shelf 31, no substrate W is stored on the fifth to fifteenth shelves 31. In this case, a processed substrate W is stored in the fifth shelf 31.

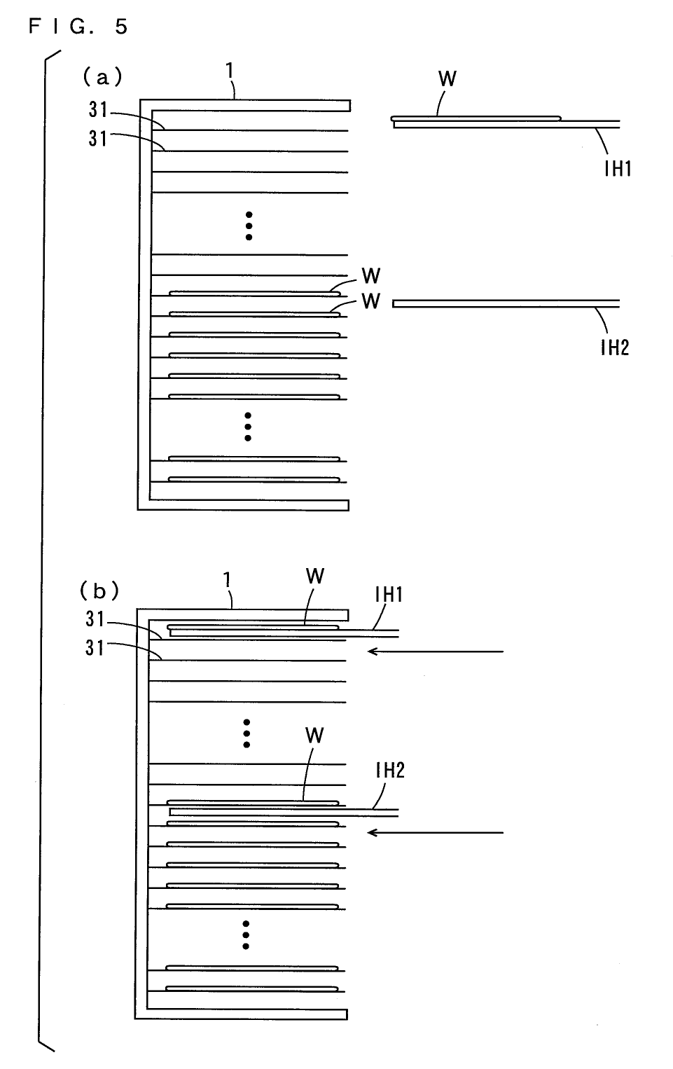

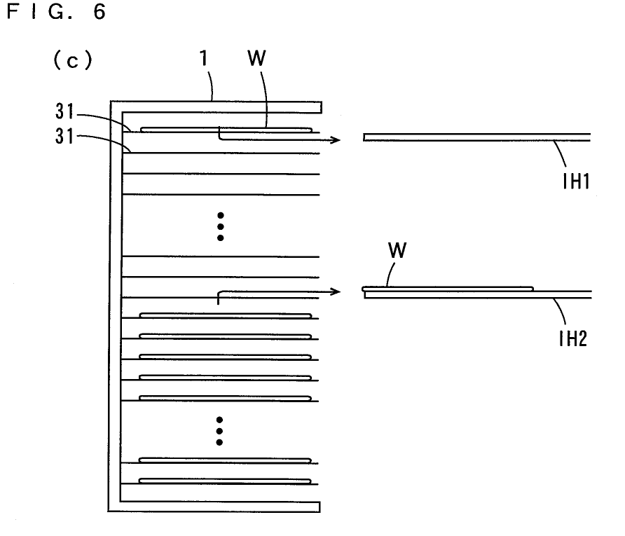

Now, the operation of taking out and storing substrates W from and to the carrier 1 by the indexer robot IR will be described more specifically. FIGS. 5 and 6 are schematic side view for use in illustrating the operation of taking out and storing substrates W from and to the carrier 1 by the indexer robot IR. With reference to FIGS. 5 and 6, an example of how an unprocessed substrate W is taken out from the twelfth shelf 31 and a processed substrate W is stored on the first shelf 31 will be described.

As shown in FIG. 5(a), the indexer robot IR is opposed to the carrier 1 as it holds a processed substrate W by the hand IH1. At the time, the hand IH1 is adjusted to the height of the first shelf 31 in the carrier 1 and the hand IH2 is adjusted to the height of the twelfth shelf 31 in the carrier 1. More specifically, the hand IH1 is adjusted to a position slightly higher than the first shelf 31 and the hand IH2 is adjusted to a position slightly lower than the twelfth shelf 31.

Note that the height of the hands IH1 and IH2 of the indexer robot IR may be adjusted while the indexer robot IR moves from the position opposed to the shuttle transport mechanism 310 to the position opposed to the carrier 1.

Then, as shown in FIG. 5(b), the hands IH1 and IH2 advance simultaneously and enter the carrier 1. As shown in FIG. 6(c), the hand IH1 is slightly lowered and withdrawn, while the hand IH2 is slightly lifted and withdrawn. In this way, the substrate W held by the hand IH1 is placed on the first shelf 31 in the carrier 1 and an unprocessed substrate W placed on the twelfth shelf 31 in the carrier 1 is taken out by the hand IH2.

In this way, according to the embodiment, the hands IH1 and IH2 can be lifted/lowered independently from each other, so that the unprocessed substrate W can be taken out from the carrier 1 and the processed substrate W can be stored in the carrier 1 at the same time.

Note that in the above example, the eleven substrates Ware present outside the carrier 1, but the number of substrates W present outside the carrier 1 varies depending upon the number of cleaning processing units 5a to 5h. For example, if the number of the cleaning processing units 5a to 5h that are used is reduced because of a trouble or the like, the number of substrates W present outside the carrier 1 can be less than eleven.

As the number of substrates W present outside the carrier 1 varies, the distance between a shelf 31 from which an unprocessed substrate W should taken out and a shelf 31 to which a processed substrate W should stored in the carrier 1 change. The distance between the IH1 and IH2 of the indexer robot IR must be changed accordingly.

According to the embodiment, the distance between the hands IH1 and IH2 of the indexer robot IR can be changed arbitrarily, and therefore storing a substrate W into the carrier 1 and taking out another substrate W from the carrier 1 can be performed exactly at the same time as the case may be.

### (1-4) Receiving and Transferring Substrates Between Indexer Robot and Shuttle Transport Mechanism

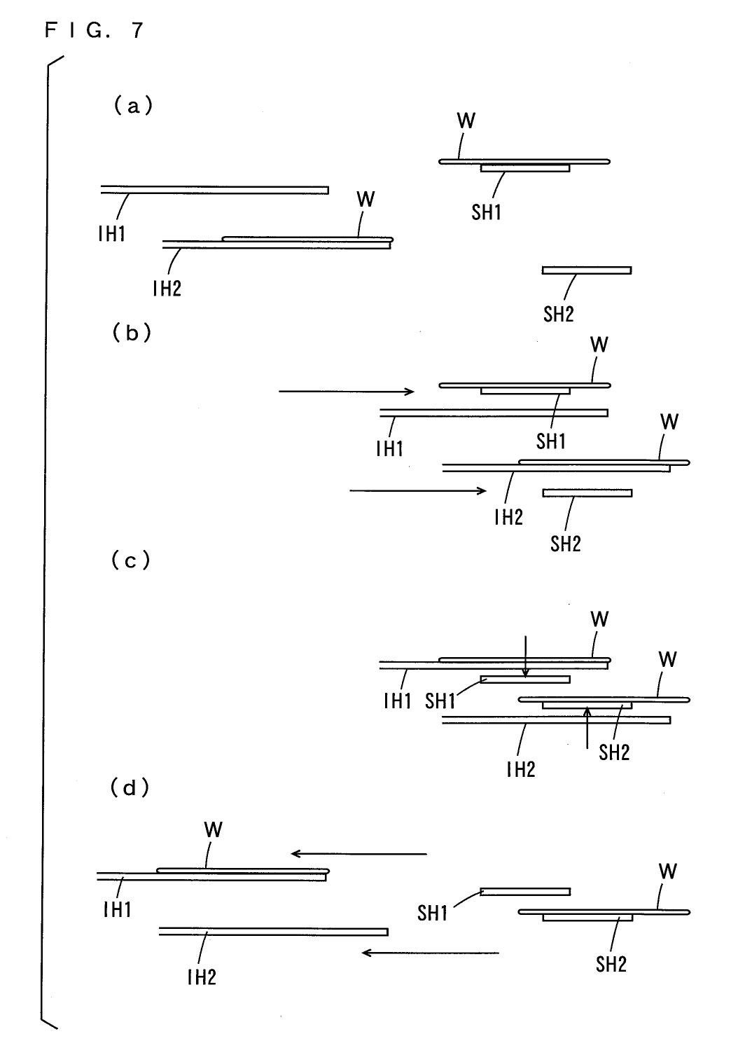

Now, the operation of receiving and transferring substrates W between the indexer robot IR and the shuttle transport mechanism 310 will be described. FIG. 7 is a schematic side view for use in illustrating the operation of receiving and transferring substrates W between the indexer robot IR and the shuttle transport mechanism 310.

As shown in FIG. 7(a), the indexer robot IR and the shuttle transport mechanism 310 are opposed to each other while an unprocessed substrate W is held by the hand IH2 of the indexer robot IR and a processed substrate W is held by the hand SH1 of the shuttle transport mechanism 310.

At the time, the hands SH1 and SH2 of the shuttle transport mechanism 310 are adjusted to be in the open state in which they are apart from each other. The hand IH1 of the indexer robot IR is adjusted to a position slightly lower than the hand SH1 of the shuttle transport mechanism 310 in the open state, and the hand IH2 of the indexer robot IR is adjusted to a position slightly higher than the hand SH2 of the shuttle transport mechanism 310 in the open state. The hands IH1 and IH2 of the indexer robot IR are shifted from each other in the horizontal direction corresponding to the hands SH1 and SH2 of the shuttle transport mechanism 310.

The heights and positions in the horizontal direction of the hands IH1 and IH2 of the indexer robot IR may be adjusted while the indexer robot IR moves from the position opposed to the carrier 1 to the position opposed to the shuttle transport mechanism 310.

Then, as shown in FIG. 7(b), the hands IH1 and IH2 of the indexer robot IR advance. This allows the hands IH1 and IH2 of the indexer robot IR to be inserted between the hands SH1 and SH2 of the shuttle transport mechanism 310.

Then, as shown in FIG. 7(c), the hands SH1 and SH2 of the shuttle transport mechanism 310 are adjusted to be in the closed state in which they are close to each other. In this way, the substrate W held by the hand SH1 of the shuttle transport mechanism 310 is transferred to the hand IH1 of the indexer robot IR and the substrate W held by the hand IH2 of the indexer robot IR is received by the hand SH2 of the shuttle transport mechanism 310. As shown in FIG. 7(d), the hands IH1 and IH2 of the indexer robot IR then withdraw.

In this way, according to the embodiment, the distance in the vertical direction between the hands SH1 and SH2 of the shuttle transport mechanism 310 is varied while the hands IH1 and IH2 of the indexer robot IR and the hands SH1 and SH2 of the shuttle transport mechanism 310 are arranged above one another in the vertical direction in an overlapped manner. Therefore, an unprocessed substrate W can be received and transferred from the indexer robot IR to the shuttle transport mechanism 310 and a processed substrate W can be received and transferred from the shuttle transport mechanism 310 to the indexer robot IR at the same time. Therefore, substrates W can be received and transferred between the indexer robot IR and the shuttle transport mechanism 310 in a short period of time.

### (1-5) Receiving and Transferring Substrates Between Shuttle Transport Mechanism and Substrate Transport Robot

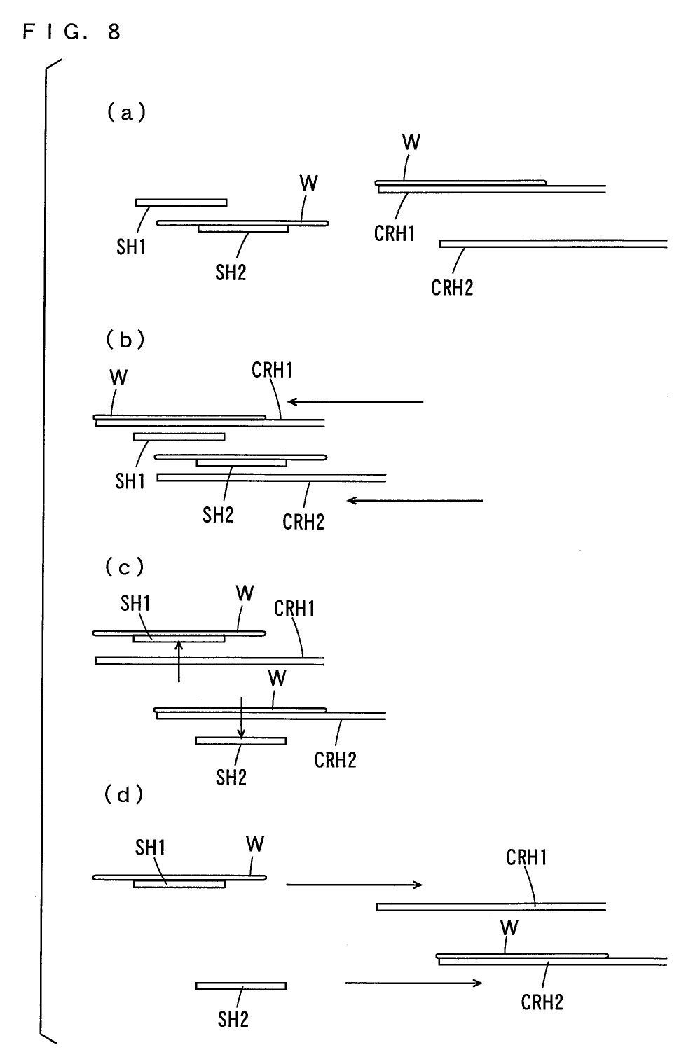

Now, the operation of receiving and transferring substrates W between the shuttle transport mechanism 310 and the substrate transport robot CR will be described. FIG. 8 is a schematic side view for use in illustrating the operation of receiving and transferring substrates W between the shuttle transport mechanism 310 and the substrate transport robot CR.

As shown in FIG. 8(a), while an unprocessed substrate W is held by the hand SH2 of the shuttle transport mechanism 310 and a processed substrate W is held by the hand CRH1 of the substrate transport robot CR, the shuttle transport mechanism 310 and the substrate transport robot CR are opposed to each other.

At the time, the hands SH1 and SH2 of the shuttle transport mechanism 310 are adjusted to be in the closed state in which they are close to each other. The hands CRH1 and CRH2 of the substrate transport robot CR are adjusted to the height to oppose the hands SH1 and SH2 of the shuttle transport mechanism 310.

As described above, the distance between the hands CRH1 and CRH2 of the substrate transport robot CR is larger than the distance between the hands CRH1 and CRH2 of the substrate transport robot CR in the closed state. Therefore, the hand CRH1 of the substrate transport robot CR is in a position higher than the hand SH1 of the shuttle transport mechanism 310 and the hand CRH2 of the substrate transport robot CR is in a position lower than the hand SH2 of the shuttle transport mechanism 310. The hands CRH1 and CRH2 of the substrate transport robot CR are shifted from each other in the horizontal direction corresponding to the hands SH1 and SH2 of the shuttle transport mechanism 310.

In this state, as shown in FIG. 8(b), the hands CRH1 and CRH2 of the substrate transport robot CR advance. This allows the hands SH1 and SH2 of the shuttle transport mechanism 310 to be inserted between the hands CRH1 and CRH2 of the substrate transport robot CR.

Then, as shown in FIG. 8(c), the hands SH1 and SH2 of the shuttle transport mechanism 310 are adjusted to be in the open state in which they are apart from each other. In this way, the substrate W held by the hand CRH1 of the substrate transport robot CR is received by the hand SH1 of the shuttle transport mechanism 310, and the substrate W held by the hand SH2 of the shuttle transport mechanism 310 is transferred to the hand CRH2 of the substrate transport robot CR. Then, as shown in FIG. 8(d), the hands CRH1 and CRH2 of the substrate transport robot CR withdraw.

In this way, according to the embodiment, the distance in the vertical direction between the hands SH1 and SH2 of the shuttle transport mechanism 310 is varied with the hands CRH1 and CRH2 of the substrate transport robot CR and the hands SH1 and SH2 of the shuttle transport mechanism 310 arranged one above another in the vertical direction in an overlapped manner. Therefore, an unprocessed substrate W is received and transferred from the shuttle transport mechanism 310 to the substrate transport robot CR and a processed substrate W is received and transferred from the substrate transport robot CR to the shuttle transport mechanism 310 at the same time. Therefore, substrates W are received and transferred between the shuttle transport mechanism 310 and the substrate transport robot CR in a short period of time.

### (1-6) Effects of First Embodiment

According to the embodiment, taking out an unprocessed substrate W from the carrier 1 and storing a processed substrate W into the carrier 1 by the indexer robot IR can be performed at the same time. In this way, the time required for the operation of the indexer robot IR during taking out and storing a substrate from/to the carrier 1 is reduced. Consequently, the throughput in the substrate processing apparatus 100 can be improved.

According to the embodiment, using the shuttle transport mechanism 310 provided with the hands SH1 and SH2 between which the distance is variable, substrates W can be received and transferred between the indexer robot IR and the shuttle transport mechanism 310 and between the shuttle transport mechanism 310 and the substrate transport robot CR in a short period. In this way, the throughput can further be improved in the substrate processing apparatus 100.

### (1-7) Other Examples of Operation

In the example described above, a unprocessed substrate W is taken out from the carrier 1 by the hand IH2 of the indexer robot IR and a processed substrate is stored in the carrier 1 by the hand IH1, while an unprocessed substrate W may be taken out from the carrier 1 by the hand IH1 of the indexer robot IR and a processed substrate may be returned to the carrier 1 by the hand IH2.

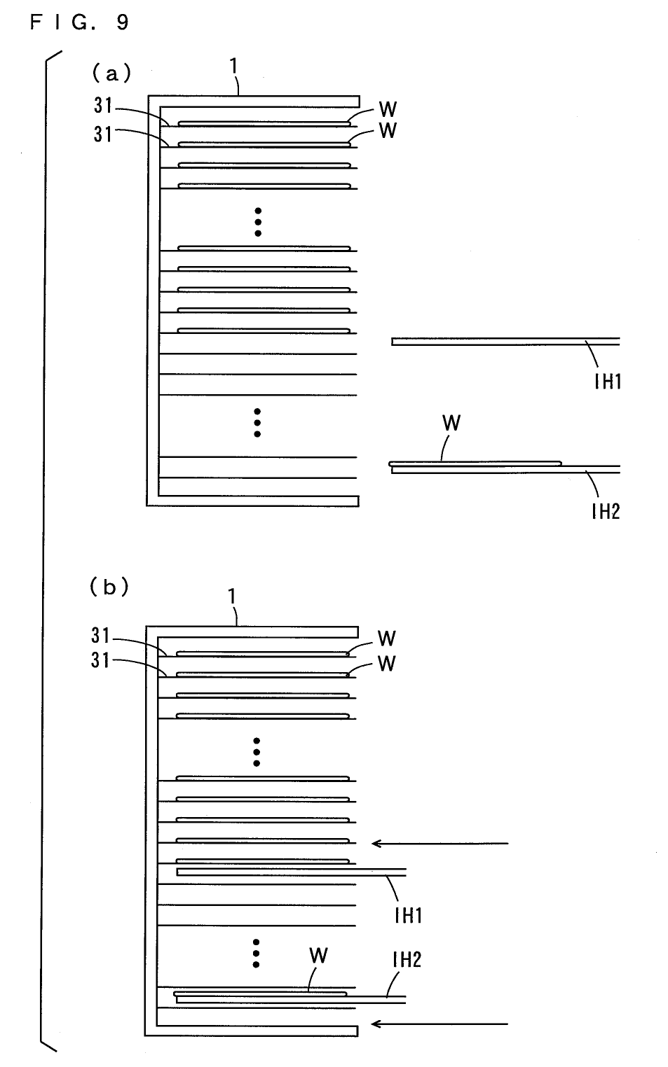

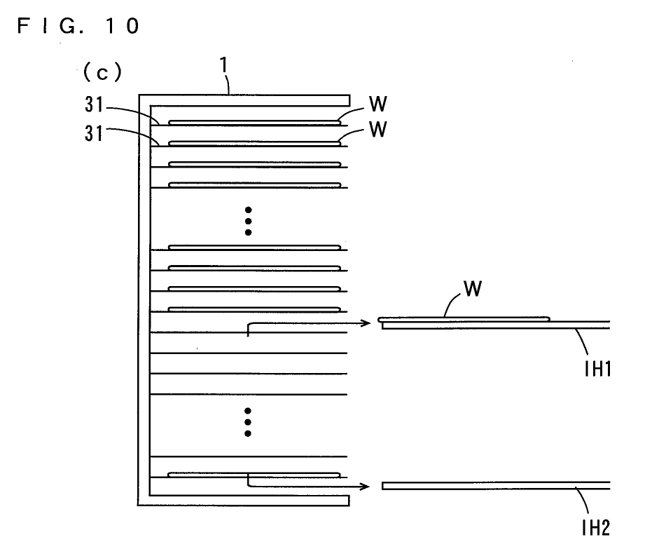

In this case, unprocessed substrates W are taken out sequentially from the twenty-fifth to first shelves 31 of the carrier 1 (FIG. 4) and processed substrates W are sequentially stored to the shelves 31 of the carrier 1 on which these substrates W were stored before the processing. Note that similarly to the above example, there are eleven shelves 31 with no substrate W stored thereon in the carrier 1. Hereinafter, more specific description will continue with reference to FIGS. 9 and 10.

FIGS. 9 and 10 are schematic side views for use in illustrating other examples of the operation of taking out and storing substrates W by the indexer robot IR. In the example in FIGS. 9 and 10, an unprocessed substrate W is taken out from the twenty-fifth shelf 31 in the carrier 1 and a processed substrate W is stored on the fourteenth shelf 31.

As shown in FIG. 9(a), while a processed substrate W is held by the hand IH2, the indexer robot IR is opposed to the carrier 1. The hand IH1 is adjusted to the height of the fourteenth shelf 31 in the carrier 1 and the hand IH2 is adjusted to the height of the twenty-fifth shelf 31 in the carrier 1. More specifically, the hand IH1 is adjusted to a position slightly lower than the fourteenth shelf 31 and the hand IH2 is adjusted to a position slightly higher than the twenty-fifth shelf 31.

Then, as shown in FIG. 9(b), the hands IH1 and IH2 advance simultaneously and enter the carrier 1. As shown in FIG. 10(c), the hand IH1 is slightly lifted and withdrawn, while the hand IH2 is slightly lowered and withdrawn. In this way, an unprocessed substrate W placed on the fourteenth shelf in the carrier 1 is taken out by the hand IH1 while the substrate W held by the hand IH2 is placed on the twenty-fifth shelf in the carrier 1.

Also in this case, the hands IH1 and IH2 of the indexer robot IR can be lifted/lowered independently from each other, so that taking out the unprocessed substrate W from the carrier 1 and storing the processed substrate W into the carrier 1 can be performed at the same time. Therefore, the time required for the operation of the indexer robot IR during taking out and storing substrates W from and to the carrier 1 is reduced.

Note that when the indexer robot IR carries out the above described operation, the shuttle transport mechanism 310 receives an unprocessed substrate W from the hand IH1 of the indexer robot IR by the hand SH1 in the first interface position and transfers a processed substrate W by the hand SH2 to the hand IH2 of the indexer robot IR.

The substrate transport robot CR receives an unprocessed substrate W from the hand SH1 of the shuttle transport mechanism 310 by the hand CRH1 and transfers a processed substrate W to the hand SH2 of the shuttle transport mechanism 310 by the hand CRH2.

### (2) Second Embodiment

A substrate processing apparatus 100 according to a second embodiment of the invention will be described regarding its difference from the first embodiment.

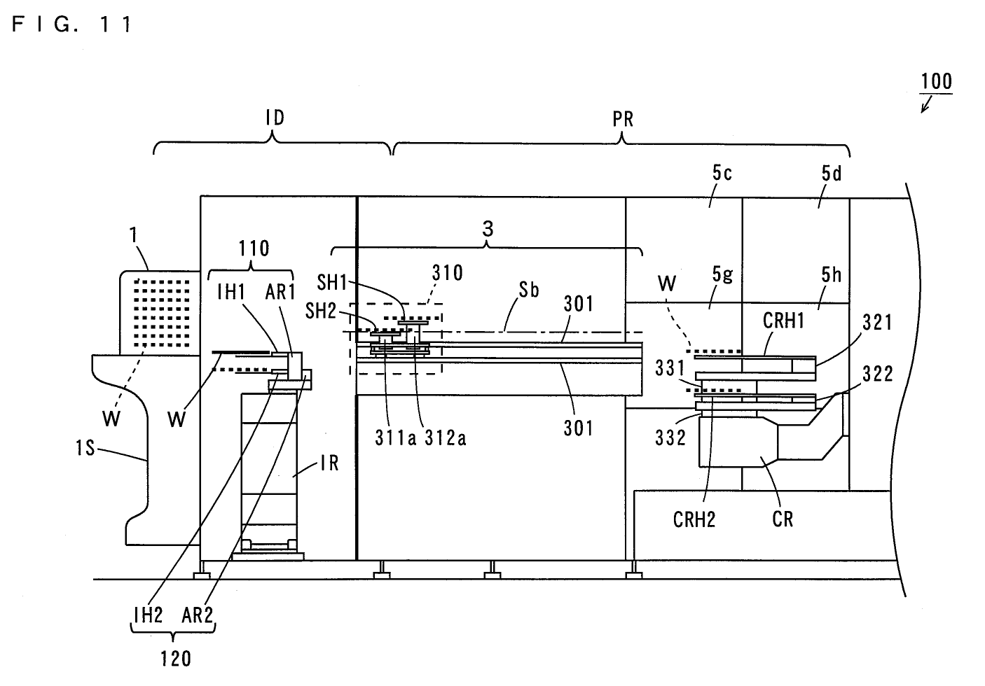

FIG. 11 is a sectional view of the substrate processing apparatus 100 according to the second embodiment. As shown in FIG. 11, in the substrate processing apparatus 100, the hands SH1 and SH2 of the shuttle transport mechanism 310 are fixed to the shuttle moving device 320 through support shafts 311a and 312a. Therefore, the distance between the hands SH1 and SH2 in the vertical direction is constant.

The substrate transport robot CR has third and fourth lifting/lowering mechanisms 331 and 332 used to lift/lower transport arms 321 and 322 independently from each other. The hands CRH1 and CRH2 are switched between the open state in which they are apart from each other and the closed state in which they are close to each other by the third and fourth lifting/lowering mechanisms 331 and 332. Note that instead of the third and fourth lifting/lowering mechanisms 331 and 332 that independently drive the transport arms 321 and 322, respectively, a switching mechanism that drives the transport arms 321 and 322 together and switches the hands CRH1 and CRH2 between the open state and the closed state may be employed.

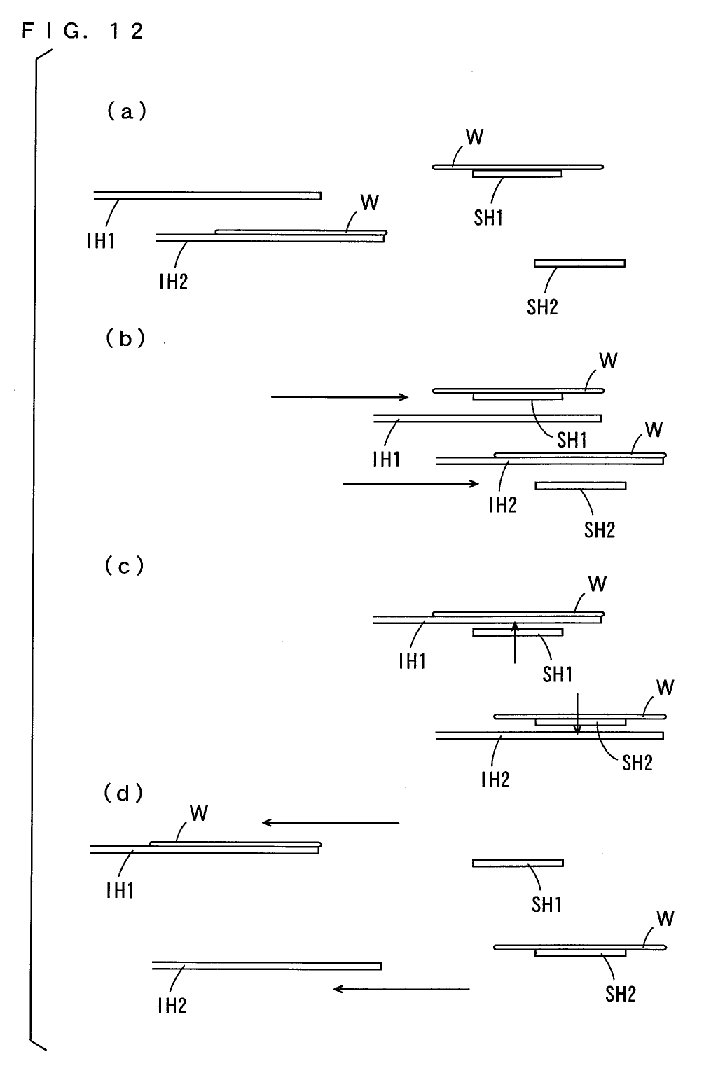

Now, the operation of receiving and transferring substrates W between the indexer robot IR and the shuttle transport mechanism 310 according to the second embodiment will be described. FIG. 12 is a schematic side view for use in illustrating the operation of receiving and transferring substrates W between the indexer robot IR and the shuttle transport mechanism 310 according to the second embodiment.

As shown in FIG. 12(a), while an unprocessed substrate W is held by the hand IH2 of the indexer robot IR and a processed substrate W is held by the hand SH1 of the shuttle transport mechanism 310, the indexer robot IR and the shuttle transport mechanism 310 are opposed to each other.

At the time, the hand IH1 of the indexer robot IR is adjusted to a position slightly lower than the height of the hand SH1 of the shuttle transport mechanism 310 and the hand IH2 of the indexer robot IR is adjusted to a position slightly higher than the height of the hand SH2 of the shuttle transport mechanism 310. The hands IH1 and IH2 of the indexer robot IR are shifted from each other in the horizontal direction corresponding to the hands SH1 and SH2 of the shuttle transport mechanism 310.

In this state, as shown in FIG. 12(b), the hands IH1 and IH2 of the indexer robot IR advance. This allows the hands IH1 and IH2 of the indexer robot IR to be inserted between the hands SH1 and SH2 of the shuttle transport mechanism 310.

Then, as shown in FIG. 12(c), the hand IH1 of the indexer robot IR is lifted and the hand IH2 is lowered. In this way, the substrate W held by the hand SH1 of the shuttle transport mechanism 310 is received by the hand IH1 of the indexer robot IR and the substrate W held by the hand IH2 of the indexer robot IR is transferred to the hand SH2 of the shuttle transport mechanism 310. As shown in FIG. 12(d), the hands IH1 and IH2 of the indexer robot IR withdraw.

In this way, according to the embodiment, while the hands IH1 and IH2 of the indexer robot IR and the hands SH1 and SH2 of the shuttle transport mechanism 310 are placed above one another in the vertical direction in an overlapped manner, the hand IH1 of the indexer robot IR is lifted and the hand IH2 is lowered. Therefore, an unprocessed substrate W can be received and transferred from the indexer robot IR to the shuttle transport mechanism 310 and a processed substrate W can be received and transferred from the shuttle transport mechanism 310 to the indexer robot IR at the same time. Therefore, substrates W can be received and transferred between the indexer robot IR and the shuttle transport mechanism 310 in a short period of time.

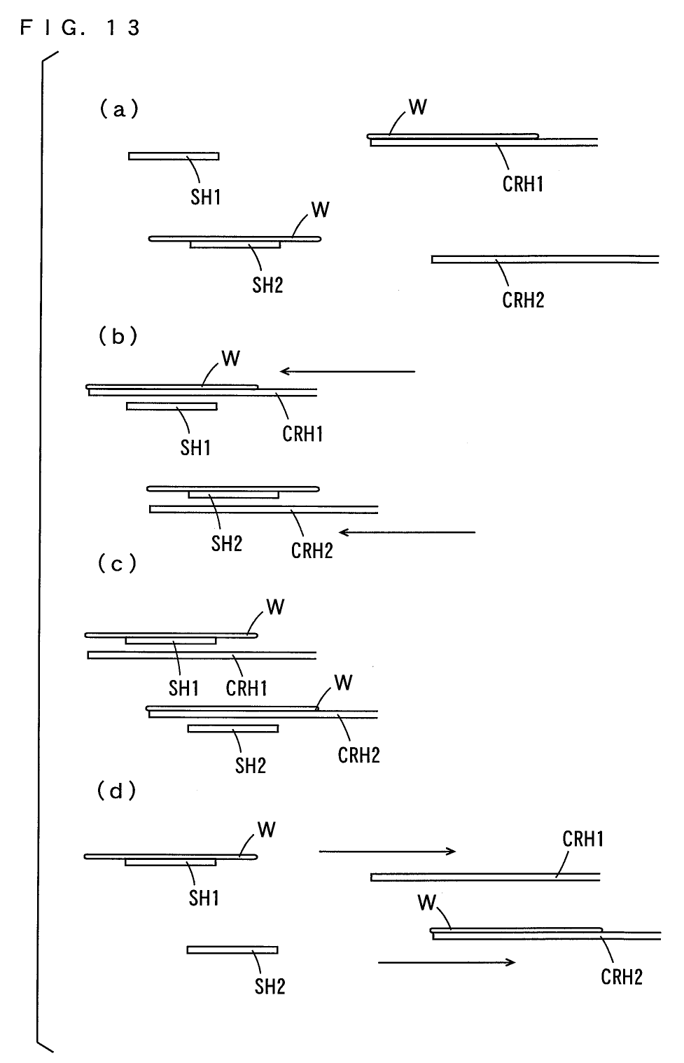

Now, the operation of receiving and transferring substrates W between the shuttle transport mechanism 310 and the substrate transport robot CR according to the second embodiment will be described. FIG. 13 is a view for use in illustrating the operation of receiving and transferring substrates W between the shuttle transport mechanism 310 and the substrate transport robot CR according to the second embodiment.

As shown in FIG. 13(a), while an unprocessed substrate W is held by the hand SH2 of the shuttle transport mechanism 310 and a processed substrate W is held by the hand CRH1 of the substrate transport robot CR, the shuttle transport mechanism 310 and the substrate transport robot CR are opposed to each other.

At the time, the hands CRH1 and CRH2 of the substrate transport robot CR are adjusted to be in the open state in which they are apart from each other. In this case, the distance between the hands CRH1 and CRH2 of the substrate transport robot CR in the vertical direction is larger than the distance between the hands SH1 and SH2 of the shuttle transport mechanism 310 in the vertical direction.

In this way, the hand CRH1 of the substrate transport robot CR is in a position slightly higher than the hand SH1 of the shuttle transport mechanism 310 and the hand CRH2 of the substrate transport robot CR is in a position slightly lower than the hand SH2 of the shuttle transport mechanism 310. The hands CRH1 and CRH2 of the substrate transport robot CR are shifted from each other in the horizontal direction corresponding to the hands SH1 and SH2 of the shuttle transport mechanism 310.

In this state, as shown in FIG. 13(b), the hands CRH1 and CRH2 of the substrate transport robot CR advance. This allows the hands SH1 and SH2 of the shuttle transport mechanism 310 to be inserted between the hands CRH1 and CRH2 of the substrate transport robot CR.

Then, as shown in FIG. 13(c), the hands CRH1 and CRH2 of the substrate transport robot CR are adjusted to be in the closed state in which they are close to each other. In this way, the substrate W held by the hand CRH1 of the substrate transport robot CR is transferred to the hand SH1 of the shuttle transport mechanism 310 and the substrate W held by the hand SH2 of the shuttle transport mechanism 310 is received by the hand CRH2 of the substrate transport robot CR. Then, as shown in FIG. 13(d), the hands CRH1 and CRH2 of the substrate transport robot CR withdraw.

In this way, according to the embodiment, while the hands SH1 and SH2 of the shuttle transport mechanism 310 and the hands CRH1 and CRH2 of the substrate transport robot CR are placed above one another in the vertical direction in an overlapped manner, the distance between the hands CRH1 and CRH2 of the substrate transport robot CR in the vertical direction is varied. Therefore, receiving and transferring an unprocessed substrate W from the substrate transport robot CR to the shuttle transport mechanism 310 and receiving and transferring a processed substrate W from the shuttle transport mechanism 310 to the substrate transport robot CR can be performed at the same time. Therefore, substrates W can be received and transferred between the shuttle transport mechanism 310 and the substrate transport robot CR in a short period of time.

Note that in the examples shown in FIGS. 12 and 13, unprocessed substrates W are transported by the hand IH2 of the indexer robot IR, the hand SH2 of the shuttle transport mechanism 310 and the hand CRH2 of the substrate transport robot CR and processed substrate W are transported by the hand IH1 of the indexer robot IR, the hand SH1 of the shuttle transport mechanism 310 and the hand CRH1 of the substrate transport robot CR but unprocessed substrates W may be transported by the hand IH1 of the indexer robot IR, the hand SH1 of the shuttle transport mechanism 310 and the hand CRH1 of the substrate transport robot CR and processed substrates W may be transported by the hand IH2 of the indexer robot IR, the hand SH2 of the shuttle transport mechanism 310 and the hand CRH2 of the substrate transport robot CR.

### (3) Third Embodiment

Now, a substrate processing apparatus 100 according to a third embodiment of the invention will be described regarding its difference from the first embodiment.

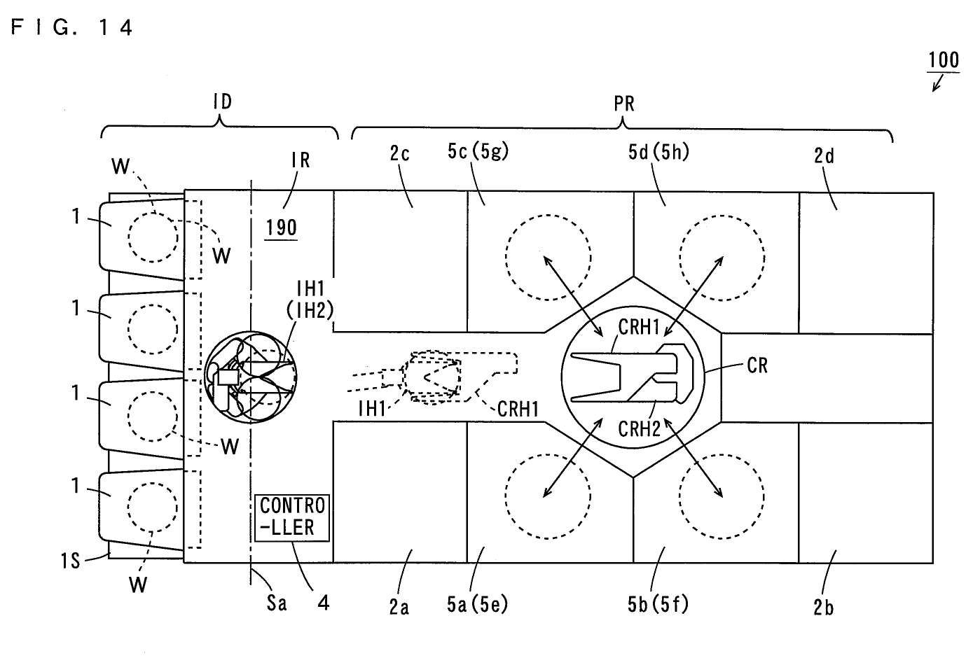

FIG. 14 is a plan view of the substrate processing apparatus 100 according to the third embodiment. As shown in FIG. 14, the substrate processing apparatus 100 is not provided with an interface 3 and substrates W are received and transferred directly between the indexer robot IR and the substrate transport robot CR. Note that the hands IH1 and IH2 of the indexer robot IR and the hands CRH1 and CRH2 of the substrate transport robot CR have such shapes that they can receive and transfer substrates W without interfering with one another.

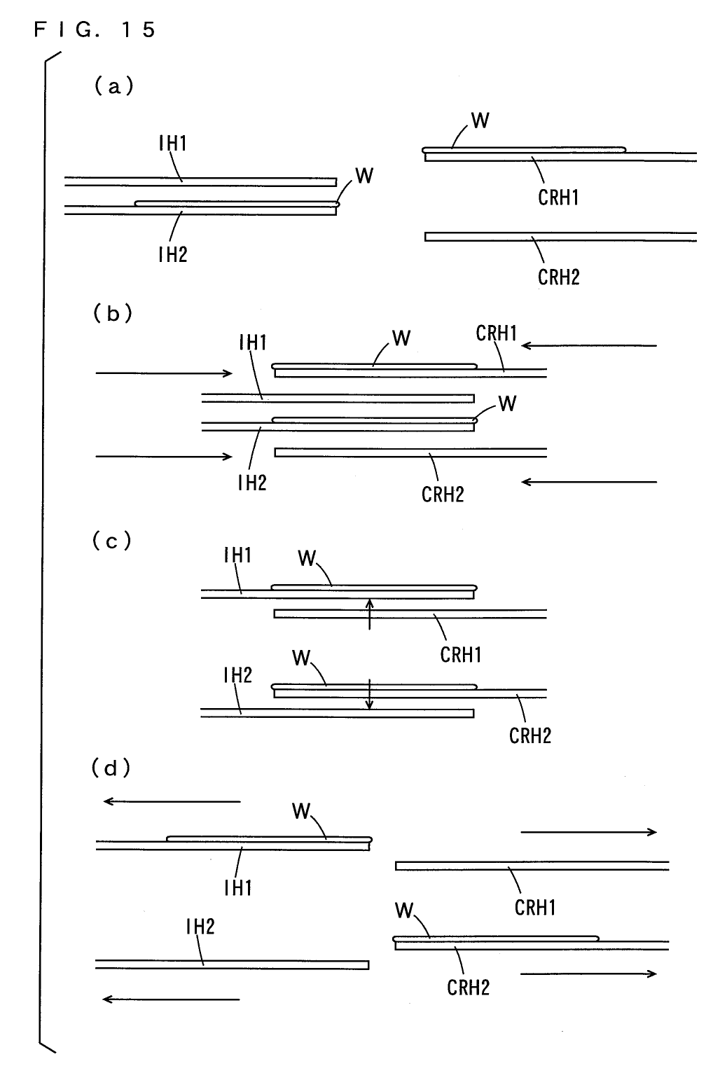

Now, the operation of receiving and transferring substrates W between the indexer robot IR and the substrate transport robot CR according to the third embodiment will be described. FIG. 15 is a view for use in illustrating the operation of receiving and transferring substrates W between the indexer robot IR and the substrate transport robot CR according to the third embodiment.

Then, as shown in FIG. 15(a), while an unprocessed substrate W is held by the hand IH2 of the indexer robot IR and a processed substrate W is held by the hand CRH1 of the substrate transport robot CR, the indexer robot IR and the substrate transport robot CR are opposed to each other.

At the time, the hand IH1 of the indexer robot IR is adjusted to a position slightly lower than the height of the hand CRH1 of the substrate transport robot CR and the hand IH2 of the indexer robot IR is adjusted to a position slightly higher than the hand CRH2 of the substrate transport robot CR.

In this state, as shown in FIG. 15(b), the hands IH1 and IH2 of the indexer robot IR and the hands CRH1 and CRH2 of the substrate transport robot CR advance. This allows the hands IH1 and IH2 of the indexer robot IR to be inserted between the hands CRH1 and CRH2 of the substrate transport robot CR.

Then, as shown in FIG. 15(c), the hand IH1 of the indexer robot IR is lifted and the hand IH2 is lowered. In this way, the substrate W held by the hand CRH1 of the substrate transport robot CR is received by the hand IH1 of the indexer robot IR and the substrate W held by the hand IH2 of the indexer robot IR is transferred to the hand CRH2 of the substrate transport robot CR. In this way, as shown in FIG. 14, the hands IH1 and IH2 of the indexer robot IR do not interfere with the hands CRH1 and CRH2 of the substrate transport robot CR.

As shown in FIG. 15(d), the hands IH1 and IH2 of the indexer robot IR and the hands CRH1 and CRH2 of the substrate transport robot CR withdraw.

In this way, according to the embodiment, while the hands CRH1 and CRH2 of the substrate transport robot CR and the hands IH1 and IH2 of the indexer robot IR are placed above one another in the vertical direction in an overlapped manner, the hand IH1 of the indexer robot IR is lifted and the hand IH2 is lowered. Therefore, an unprocessed substrate W is received and transferred from the indexer robot IR to the substrate transport robot CR and a processed substrate W is received and transferred from the substrate transport robot CR to the indexer robot IR at the same time. Therefore, substrates W can be received and transferred between the indexer robot IR and the substrate transport robot CR in a short period of time.

Note that in the example shown in FIG. 15, an unprocessed substrate W is transported by the hand IH2 of the indexer robot IR and the hand CRH2 of the substrate transport robot CR and a processed substrate W is transported by the hand IH1 of the indexer robot IR and the hand CRH1 of the substrate transport robot CR, while an unprocessed substrate W may be transported by the hand IH1 of the indexer robot IR and the hand CRH1 of the substrate transport robot CR and a processed substrate W may be transported by the hand IH2 of the indexer robot IR and the hand CRH2 of the substrate transport robot CR.

### (4) Other Embodiments

According to the embodiments described above, the carrier 1 is capable of storing 25 substrates W, but a carrier 1 capable of storing substrates W as many as a number other than 25 may be used. Note that the distance between a shelf 31 from which an unprocessed substrate W should be taken out and a shelf 31 to which a processed substrate W should be stored varies depending on the kind of the carrier 1 used. Therefore, depending on the kind of the carrier 1, the distance between the hands IH1 and IH2 of the indexer robot IR during taking out and storing substrates W is adjusted. Therefore, substrates W can simultaneously be taken out and stored from and to each of various kinds of carriers 1.

Note that as the carrier 1, an OC (Open Cassette), a FOUP (Front Opening Unified Pod), a SMIF (Standard Mechanical Interface) pod, or the like may be used.

In the above-described embodiments, an multi-joint type transport robot that linearly advances/withdraws the hands by moving the joints is employed each for the indexer robot IR and the substrate transport robot CR, but a linear type transport robot that linearly advances/withdraws the hands by sliding the hands with respect to substrates W may be employed.

### (5) Correspondences between Elements in Claims and Elements in Embodiments

In the following paragraphs, non-limiting examples of correspondences between various elements recited in the claims below and those described above with respect to various preferred embodiments of the present invention are explained.

In the embodiments described above, the indexer ID is an example of the indexer, the carrier 1 is an example of the storing container, the carrier platform 1S is an example of the container platform, the indexer robot IR is an example of the first substrate transport device, the hands IH1 and IH2 are an example of the first and second substrate holders, the rotation mechanism 150 and the moving mechanism 160 are an example of the moving mechanism, the arms AR1 and AR2 are an example of the first and second advancing/withdrawing mechanisms, and the first and second lifting/lowering mechanisms 130 and 140 are an example of the first and second lifting/lowering mechanisms.

The shuttle transport mechanism 310 is an example of the interface device, the hands SH1 and SH2 are an example of the third and fourth substrate holders, the lifting cylinders 311 and 312 are an example of the first opening/closing driving mechanism, the cleaning processing units 5a to 5h are an example of the processing unit, the substrate transport robot CR is an example of the second substrate transport device, the hands CRH1 and CRH2 are an example of the fifth and sixth substrate holders, the third and fourth lifting/lowering mechanisms 331 and 332 are an example of the second opening/closing mechanism.

As various elements recited in the claims, various other elements having structures or functions as recited in the claims can be also used.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A substrate processing apparatus, comprising a processing section used to carry out processing to a substrate; and
an indexer used to carry in/out a substrate to/from said processing section,
said indexer comprising:
a container platform where a storing container that stores a plurality of substrates in a plurality of stages is placed; and
a first substrate transport device that transports a substrate between said storing container placed at said container platform and said processing section,
said first substrate transport device comprising:
first and second substrate holders provided one above the other in the vertical direction to hold a substrate;
a moving mechanism provided movably in an approximately horizontal direction and rotatably around an approximately vertical axis;
first advancing/withdrawing mechanism that advances/withdraws said first substrate holder in an approximately horizontal direction;
second advancing/withdrawing mechanism that advances/withdraws said second substrate holder in an approximately horizontal direction;
first lifting/lowering mechanism that lifts/lowers said first advancing/withdrawing mechanism with respect to said moving mechanism in an approximately vertical direction; and
second lifting/lowering mechanism that lifts/lowers said second advancing/withdrawing mechanism with respect to said moving mechanism in an approximately vertical direction.

2. The substrate processing apparatus according to claim 1, wherein said storing container has a plurality of shelves each used to store a substrate,
said first substrate transport device is opposed to said storing container by said moving mechanism while holding a substrate by the first substrate holder and holding no substrate by the second substrate holder,
said first substrate holder is adjusted to the height of a shelf in said storing container on which no substrate is stored by said first lifting/lowering mechanism and the second substrate holder is adjusted to the height of a shelf in said storing container on which a substrate is stored by said second lifting/lowering mechanism,
said first and second substrate holders are simultaneously advanced into said storing container by said first and second advancing/withdrawing mechanisms,
said first substrate holder is lowered by said first lifting/lowering mechanism while said second substrate holder is lifted by said second lifting/lowering mechanism, and
said first and second substrate holders are simultaneously withdrawn from said storing container by said first and second advancing/withdrawing mechanisms.

3. The substrate processing apparatus according to claim 1, wherein said storing container has a plurality of shelves each used to store a substrate,
said first substrate transport device is opposed to said storing container by said moving mechanism while holding no substrate by the first substrate holder and holding a substrate by the second substrate holder,
said first substrate holder is adjusted to the height of a shelf in said storing container on which a substrate is stored by said first lifting/lowering mechanism while the second holder is adjusted to the height of a shelf in said storing container on which no substrate is stored by said second lifting/lowering mechanism,
said first and second substrate holders are simultaneously advanced into said storing container by said first and second advancing/withdrawing mechanisms,
said first substrate holder is lifted by said first lifting/lowering mechanism while said second substrate holder is lowered by said second lifting/lowering mechanism, and
said first and second substrate holders are simultaneously withdrawn from said storing container by said first and second advancing/withdrawing mechanisms.

4. The substrate processing apparatus according to claim 1, further comprising an interface device that receives and transfers substrates between said processing section and said indexer, wherein said interface device comprises:
third and fourth substrate holders provided one above the other in the vertical direction to hold a substrate; and
a first opening/closing driving mechanism that drives said third and fourth substrate holders in a direction in which said third and fourth substrate holders become apart from each other and in a direction in which said third and fourth substrate holders come closer to each other,
said processing section comprises:
a processing unit that processes a substrate; and
a second substrate transport device that transports a substrate between said interface device and said processing unit, and
said second substrate transport device has fifth and sixth substrate holders provided one above the other in the vertical direction to hold a substrate.

5. The substrate processing apparatus according to claim 1, further comprising an interface device that receives and transfers substrates between said processing section and said indexer, wherein said interface device comprises third and fourth substrate holders provided one above the other in the vertical direction to hold a substrate,
said processing section comprises:
a processing unit that processes a substrate; and
a second substrate transport device that transports a substrate between said interface device and said processing unit, and
said second substrate transport device comprises:
fifth and sixth substrate holders provided one above the other in the vertical direction to hold a substrate; and
a second opening/closing driving mechanism that drives said fifth and sixth substrate holders in a direction in which said fifth and sixth substrate holders become apart from each other and in a direction in which said fifth and sixth substrate holders come closer to each other.

6. The substrate processing apparatus according to claim 1, wherein said processing section comprises:
a processing unit that processes a substrate; and
a second substrate transport device that transports a substrate between said first substrate transport device and said processing unit, and
said second substrate transport device has fifth and sixth substrate holders provided one above the other in the vertical direction to hold a substrate.
